(19) United States
(12) Patent Application Publication
(10) Pub. No.: US 2013/0264686 A1
(43) Pub. Date: Oct. 10, 2013

(54) SEMICONDUCTOR WAFER PROCESSING

(71) Applicants: Iriguchi Shoichi, Beppu City (JP); Sada Hiroyuki, Beppu City (JP); Yano Genki, Beppu City (JP)

(72) Inventors: Iriguchi Shoichi, Beppu City (JP); Sada Hiroyuki, Beppu City (JP); Yano Genki, Beppu City (JP)

(73) Assignee: Texas Instruments Incorporated, Dallas, TX (US)

(21) Appl. No.: 13/440,230

(22) Filed: Apr. 5, 2012

(51) Int. Cl. H01L 21/78; H01L 23/00

(52) U.S. Cl. 257/618; 438/464; 257/E21.599; 257/E23.002

(57) ABSTRACT

One embodiment of a method of processing a semiconductor wafer having a peripheral portion includes providing external support structure and restraining radially inward displacement of the wafer peripheral portion with the external support structure.

### BACKGROUND

Integrated circuits, also referred to as “IC's” or “semiconductor chips” or simply “chips,” are electronic circuits made by diffusion of trace elements into the surface of thin substrates of semiconductor material such as silicon. Integrated circuits were first produced in the mid Twentieth Century. Because of their small size and relatively low production cost, integrated circuits are now used in most modern electronics. Semiconductor chips are typically mass produced in the form of a single wafer that contains a large number of identical integrated circuits. The wafer is cut (“singulated”) into a number of individual semiconductor chips referred to as “dies” or “dice.”

Dies are usually “packaged” to prevent damage to the dies and to facilitate attachment of the dies to circuit boards. Various packaging materials and processes have been used to package integrated circuit dies. One conventional packaging method involves mounting individual dies in a predetermined pattern on a substrate strip. The dies mounted on the substrate strip are then encapsulated in a plastic material, such as by a transfer molding process. Next, the encapsulated dies are singulated into individual integrated circuit packages by cutting the encapsulated die/substrate strip in accordance with the predetermined die mounting pattern. Typical cutting tools include saws and punches. Each integrated circuit package generally includes at least one die and the underlying portion of the substrate strip on which it was mounted, as well as encapsulating material which typically covers the die. The underlying substrate strip is sometimes a lead frame to which the die is electrically connected and which, in turn, is adapted to be connected to a printed circuit board (“PC” board).

Over the years, integrated circuits and the circuit boards to which they are attached have become physically smaller and more complex. One relatively new technology is known alternately as “wafer scale packaging,” “wafer level chip scale packaging,” “wafer level chip size packaging” and other similar names. The phrase “wafer scale packaging” (“WSP”) will be used herein. Using WSP packaging, unpackaged dies, i.e., dies with no surrounding layer of protective encapsulation, are mounted on printed circuit boards. The structure needed for electrical connection of dies to a printed circuit board is usually fabricated on a first surface of the dies while the dies are still integrally connected together in a single wafer. For example, in one form of WSP packaging, various metal layers are formed on a first surface of dies at the wafer level. In some cases other electrical contacts or circuitry are formed on a second surface of the die. After wafer singulation such dies may be attached, first side down, to a PC board and may be further electrically connected to a PC board, wiring boards, other dies, etc., by circuitry on the second side. Such WSP dies have the advantage of being considerably smaller than conventionally packaged IC dies and are thus ideal for applications, such as cellular phones and digital tablets, where the associated PC boards must have a small footprint.

### BRIEF DESCRIPTION OF THE DRAWINGS

FIG. 1 is an isometric view of a silicon wafer positioned front side up;

FIG. 2 is a cross sectional view of the silicon wafer of FIG. 1 having a front side metal layer applied thereto;

FIG. 3 is a cross sectional view of the silicon wafer and metal layer of FIG. 2 in a bowed state;

FIG. 4 is a cross sectional elevation view of a wafer with a metal layer applied to its front side in which the back side of the wafer has been ground according to the Taiko process;

FIG. 5 is an exploded isometric view of a silicon wafer, support sheet, and support frame;

FIG. 6 is a top plan view of the silicon wafer, support sheet and support frame of FIG. 5 in an assembled state, with the wafer, support sheet and support frame in a front side down orientation;

FIG. 7 is a schematic illustration of a silicon wafer with a front side metal layer and attached back grinding tape prior to back side grinding and polishing;

FIG. 8 is a schematic illustration of a silicon wafer with a front side metal layer and attached back grinding tape after back side grinding and polishing;

FIG. 9 is a schematic illustration of the silicon wafer assembly shown in FIG. 8, attached to a support sheet which is in turn attached to a support frame;

FIG. 10 is a side elevation view identical to that of FIG. 9 except including a back side metal layer applied to the silicon wafer;

FIG. 11 is a schematic elevation view of an assembly identical to FIG. 10 except inverted and including dicing tape applied to the front side metal layer and support sheet;

FIG. 12 is a schematic elevation view identical to FIG. 11 except inverted and showing the back grind tape being removed with peeling tape;

FIG. 13 is a schematic elevation view identical to FIG. 12 except with the back grind tape removed and showing a dicing saw;

FIG. 14 is a schematic elevation view identical to FIG. 10, except inverted, and showing the use of peeling tape to remove the support sheet;

FIG. 15 is a schematic elevation view identical to FIG. 14, except with the support sheet removed;

FIG. 16 is a schematic elevation view identical to FIG. 15, except with dicing tape applied to the back side metal layer, exposed back side silicon, and the support frame;

FIG. 17 is a side elevation view identical to FIG. 16, except inverted and illustrating the removal of back grind tape with peeling tape;

FIG. 18 is a schematic elevation view identical to FIG. 17, except with the back grind tape removed and showing a dicing saw;

FIG. 19 is an isometric view of a die fabricated from a portion of the wafer of FIG. 1;

FIG. 20 is a flow chart illustrating an embodiment of a method of processing a semiconductor wafer; and

FIG. 21 is a flow chart illustrating another embodiment of a method of processing a semiconductor wafer.

### DETAILED DESCRIPTION

This disclosure relates generally to a method of processing a semiconductor wafer 10 (“wafer”) that tends to prevent cracking of the wafer due to wafer bowing, i.e. drooping of the wafer in the center when the wafer is picked up or vertically supported near its periphery. Damage is prevented by engaging a peripheral portion 20 of the wafer 10 with external support structure 50, 60 that restrains radially inward displacement of the wafer peripheral portion 20. In one embodiment the method is used in a process that provides a metal layer 30 on a front side 12 and another metal layer 74 on a back side 14 of the wafer 10, FIGS. 13 and 18. Having thus described a method of processing a wafer in general terms, the method and associated structure will now be described in detail.

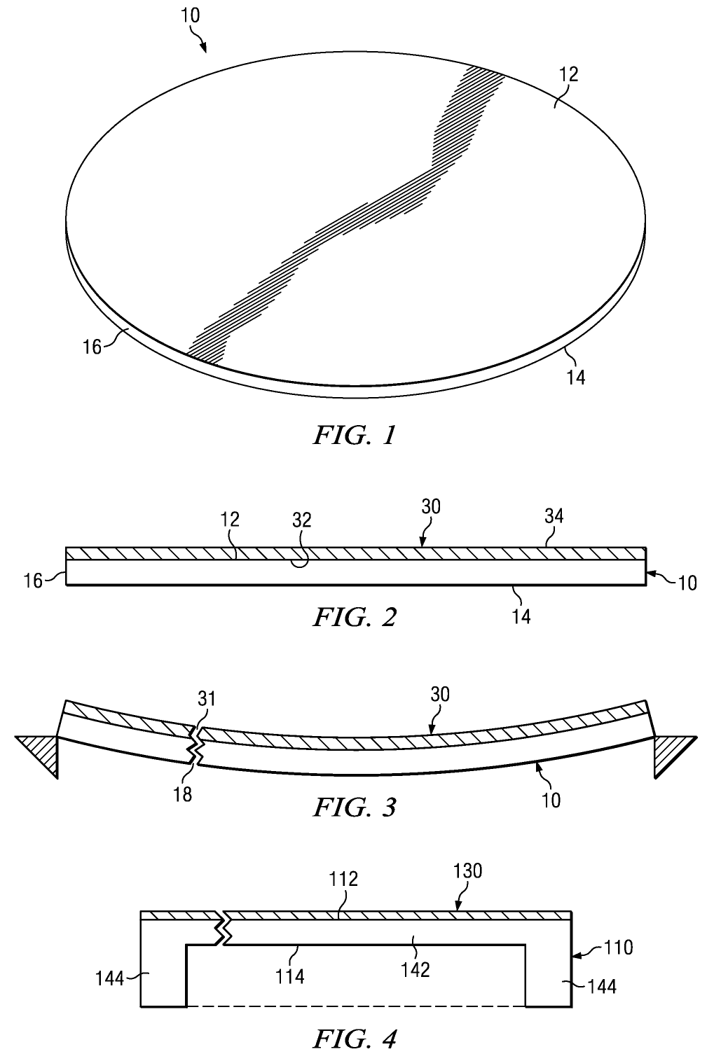

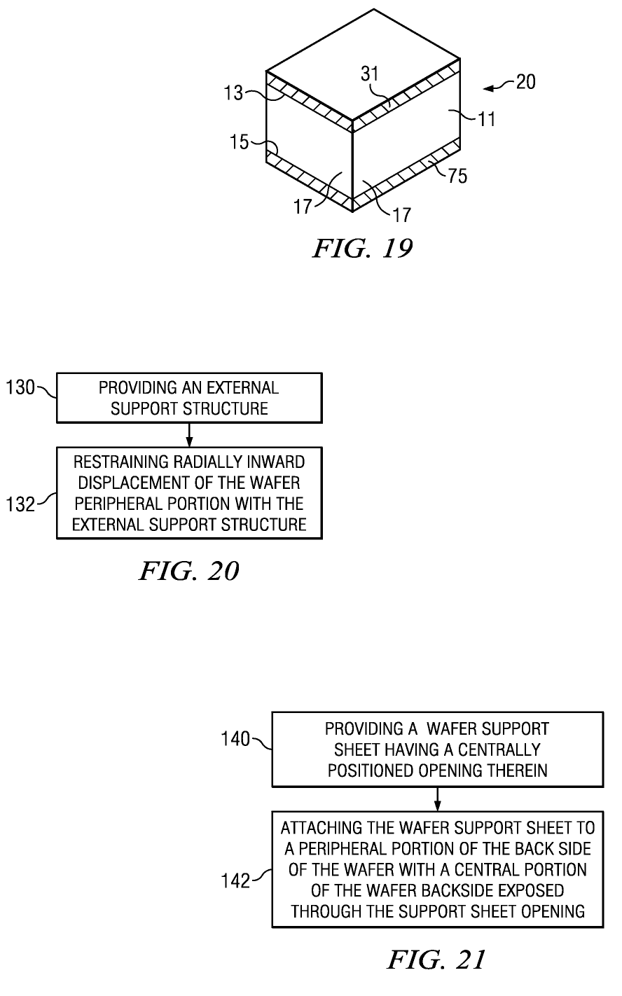

FIG. 1 illustrates a semiconductor wafer 10 having a front side 12, a back side 14, and a peripheral edge 16. FIG. 2 is a cross sectional elevation view of the silicon wafer 10 of FIG. 1 after application of a front side metal layer 30 and after grinding and polishing the back side 14, all of which is conventional and well known in the art. The purpose of back side grinding is to reduce the thickness of the silicon layer so as to reduce the thickness of silicon dies 20, FIG. 19, which are singulated from the wafer 10 in subsequent operations. The purpose of polishing is to produce a smooth surface after grinding, which facilitates bonding of a subsequently applied metal layer 74, e.g. FIG. 10, to the back side surface 14. Various methods by which a metal layer may be applied to a wafer, as well as grinding and polishing of wafers, are well known in the art and will thus not be further described herein.

It is known in the art that semiconductor wafers may be produced in various diameters and thicknesses. The wafer 10, typically a circular disc, may be formed from various semiconductor materials such as silicon and gallium. A typical wafer diameter may be about 8-12 in. A typical wafer thickness before back side grinding may be about 800 μm, and a typical wafer thickness after grinding may be about 50 μm. As is well known in the art, a metal layer applied to a wafer may include a series of patterned metal sub layers, for example: an under metal bump sub layer, a customer passivation sub layer, a redistribution sub layer, one or more polyamide sub layers and a metal pad sub layer. A typical thickness of front side metal layer 30 may be about 5 μm, but a wide range of thicknesses are possible depending upon the particular type of dies that are being produced.

As illustrated in FIG. 3, a silicon wafer 10 of the above-described exemplary dimensions is subject to bowing when vertically supported near its peripheral edge 16. Such bowing causes stress in the silicon wafer 10 which may result in a crack 18 being formed therein. The crack 18 may propagate into the front side metal layer 30 causing a crack 31.

One process, which may be applied to a wafer to reduce the chance of wafer cracking, is known as the Taiko process and is illustrated schematically in FIG. 4. In this process, after application of a metal layer 130 to a front side surface 112 of a wafer 110 the back side surface 114 and a central body portion 142 of the wafer is ground down to reduce its thickness, but a peripheral flange portion 144 of the wafer is not reduced in thickness. (The back side surface before grinding is illustrated by a dashed line) Thus, the resulting wafer resembles a bottle cap having a thin central body portion 142 and a relatively thick, downwardly extending peripheral flange portion 144. The thickness of the flange portion 144 enables the wafer 10 to remain relatively stiff and thus less subject to bowing than if the flange 144 were ground down like the central body portion 142. However, a problem with the resulting cap-shaped wafer 110 is that polishing of the back side 114 is difficult or impossible because of the cap-shape configuration. A typical wafer 144 after application of the Taiko process, including the metal layer 130, is about 50 μm thick. The wafer thickness in the flange portion 44 may be about 760 μm. However, even when the Taiko process is used, the resulting wafer 110 remains highly subject to cracking, particularly in the reduced thickness area adjacent to the peripheral flange 144.

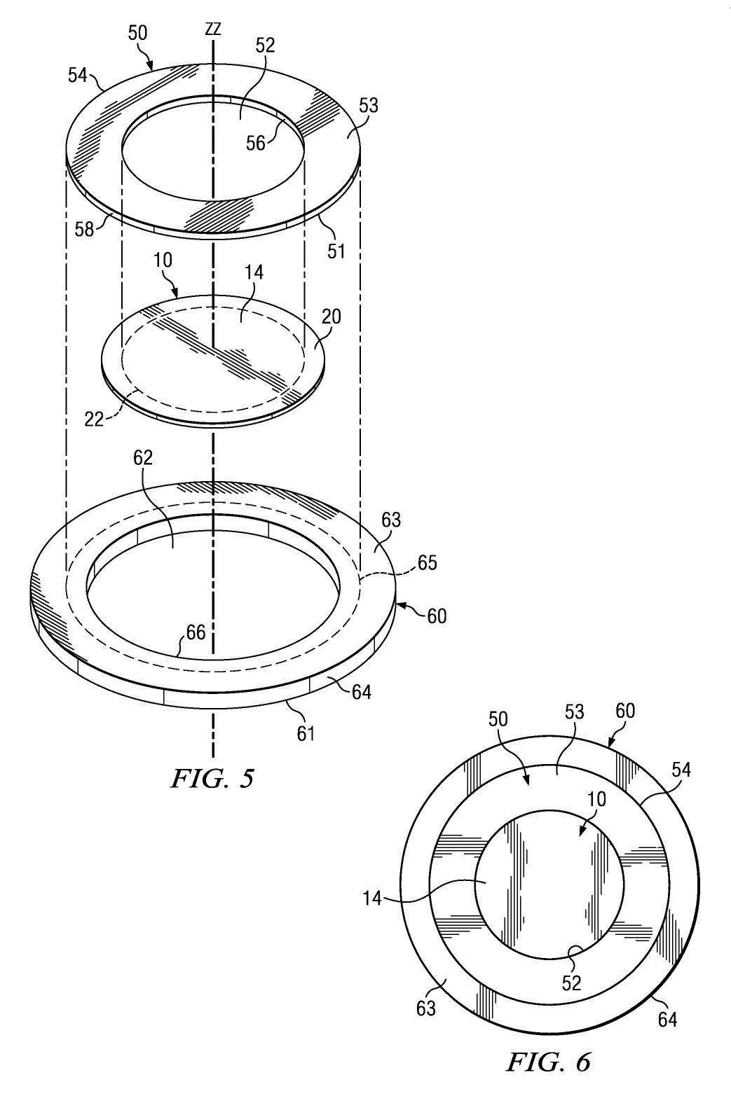

Applicants have discovered a method for supporting a silicon wafer 10 during processing which reduces the chance of cracking. This method enables the wafer back side 14 to be ground and polished much more easily than the Taiko process. FIG. 5 is an exploded perspective view illustrating structure that may be used to support a wafer 10. FIG. 6 is a top plan view of this structure and a supported wafer 10. The wafer 10 in FIGS. 5 and 6 is inverted with respect to its position in FIGS. 1-3. In the embodiment of FIGS. 5 and 6, the wafer 10 may have a diameter of about 200 mm and a thickness of about 50 μm. The wafer support structure includes a support sheet 50 having a front side 51 and an opposite back side 53. In one nonlimiting embodiment the support sheet 50 may have a relatively flexible, laminated structure including a polyvinyl chloride layer, an adhesive layer which may be UV curable acrylic and a release film which may be polyester. The thickness of the sheet 50 in a typical embodiment may be about 90-160 μm. The support sheet 50 may be ring-shaped having a central opening 52 which may have a typical diameter of about 185 mm. The ring has an outer periphery 58 with a diameter which may be about 270 mm. A support frame 60 may be constructed from a relatively rigid, high strength material such as stainless steel or polyamide-based resin. The support frame 60 may also be a ring shape structure having a front side 61, a back side 63, a central opening 62, which may have a diameter of about 250 mm, and an outer peripheral edge 64 which may have a diameter of about 296 mm. In one embodiment the thickness of the support frame may be about 1.2 mm.

As shown by FIG. 5, the support sheet 50 is adapted to engage and be adhered to a peripheral region 20 on the front side 12 of the silicon wafer 10. Any suitable adhesive, such as silicon, acrylic or polyvinylchloride (PVC) may be used. The opening 52 of the support sheet and the silicon wafer 10 may be coaxial having common central axis ZZ, such that the circumference 56 of opening 52 corresponds to the inner circumference 22 of region 20 on the wafer 10 as shown in FIG. 5. An outer edge 54 of the support sheet 50 extends beyond the peripheral edge 16 of the silicon wafer 10 and engages back side 63 of the support frame 60 in an annular region extending radially inwardly from circle 65 to the edge of opening 62. Axis ZZ may also be the central axis of support frame 60. The size of the central opening 62 of the support frame is sufficiently large to enable the silicon wafer 10 to be received therethrough. Thus, the front side 51 of support sheet 50 may be attached to the back side 14 of wafer 10 and then attached to the back side 63 of support frame 60. The wafer 10 projects into the opening 62 in the support frame as best illustrated in FIG. 9. FIG. 6 is a top plan view of the structure of FIG. 5 after assembly showing the back sides 14, 53, 63 of the wafer 10, support sheet 50 and support frame 60, respectively.

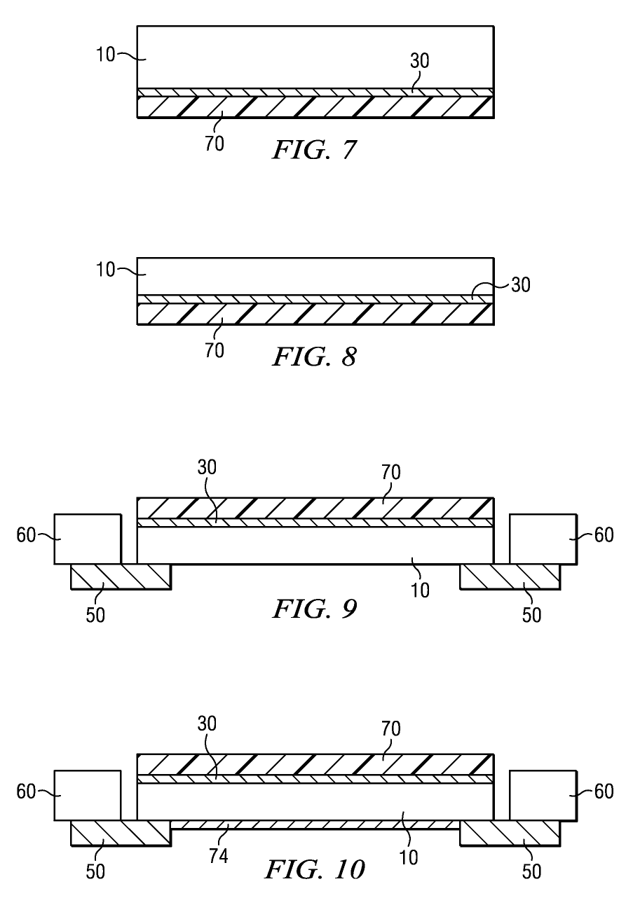

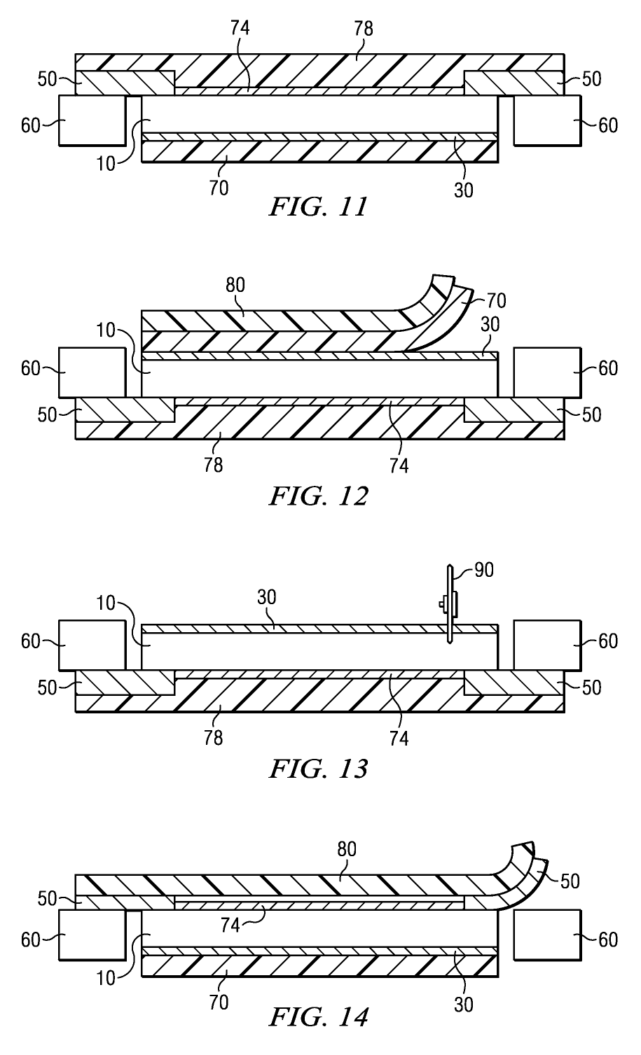

Initially, as illustrated in FIG. 7, an unprocessed silicon wafer 10 is processed to provide the front side 12 with a metal layer 30, which may comprise multiple metal sub layers, applied thereto as by conventional metal layer forming processes known in the art. This metal layer 30 applied to the front side 12 of the wafer is sometimes referred to herein as the “front side metal layer 30” and may have a thickness of about 5 μm. As previously mentioned, in typical embodiments, the wafer 10 may have a diameter of about 8-12 inches and may have a pre-grinding thickness of about 740 μm. The wafer 10 with the front side metal layer 30 has back grind (“BG”) tape 70 applied thereto and then goes through a back grinding process. Back grinding is a conventional process known in the art. The grinding process reduces the thickness of the wafer substantially, e.g., in one embodiment the thickness is reduced to about 50 μm, FIG. 8. After grinding, the reduce thickness silicon wafer 10 with attached front side metal layer 30 and back grind tape 70 is adhesively attached to support sheet 50 as described above with reference to FIGS. 5 and 6. In the embodiment illustrated in FIG. 9 a BG tape 70 is positioned uppermost and the support sheet 50 is positioned lowermost. Next, the assembly shown in FIG. 9 is transferred to a back side metal coating station at which a back side metal layer 74 is applied to the wafer back side 14. This back side metal layer 74, like the front side metal layer 30, may comprise a combination of metal sub layers. Next, as illustrated by FIG. 11, the assembly of FIG. 10 may be inverted such that BG tape 70 is positioned lower most. Dicing tape 78 is then applied to the back side surface 53 of the support sheet 50 and to the back side metal layer 74.

As illustrated in FIG. 12, the assembly of FIG. 11 is then inverted such that the dicing tape 78 is positioned lower most and BG tape 70 is positioned uppermost and a layer of peeling tape 80 is then applied to the BG tape. The adhesive of the peeling tape is stronger than the adhesive of the BG tape such that removing the peeling tape also removes the BG tape from the front side metal layer 30. Next, as illustrated in FIG. 13, the assembly of FIG. 12 with the BG tape removed is placed at a dicing station where the wafer is cut, as by dicing saw 90, into a plurality of individual dies 100, FIG. 19. During this dicing process, the portion of the silicon wafer 10 which does not have back side metal coating 74 applied thereto, is trimmed off and removed as scrap.

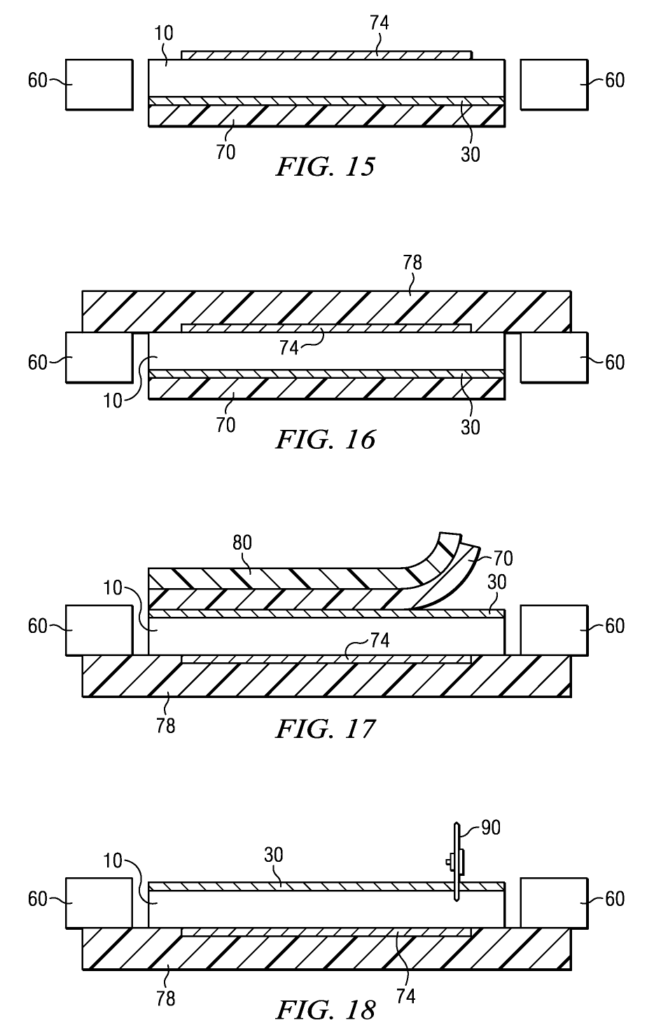

FIGS. 14-18 illustrate a slightly different methodology for processing the wafer 10 into a plurality of dies 100. The process of FIGS. 14-18 is identical to the process described above up through FIG. 10. However at this point, according to this alternative process, the assembly of FIG. 10 is inverted such that BG tape 30 is positioned lowermost and a layer of peeling tape 80 is applied to the top of the assembly in contact with the back side 53 of support sheet 50. The peeling tape 80 is then used to remove support sheet 50 such that the back side metal layer 74 and a peripheral portion of the wafer back side 14 is exposed.

Next, as illustrated in FIG. 16, dicing tape 78 is applied in contact with the back side metal layer 74, a ring shaped portion of the back side 14 of the wafer and the support frame 60.

Next, as illustrated in FIG. 17, the assembly of FIG. 16 is inverted such that the dicing tape 78 is positioned lowermost and a peeling tape 80 is applied to the BG tape 70 and used to remove it. The assembly illustrated in FIG. 18 is then diced as by a wafer saw 90 to form a plurality of individual dies 100, FIG. 19. It will be appreciated from the above that the dies 100 formed by the described processes have a central silicon substrate 17 with a front side 13 and a back side 15 corresponding generally to the front side 12 and back side 14 of wafer 10. The planar cuts provided by the dicing saw 90 produce generally planar lateral side surfaces 17 on each of the resulting dies 100.

FIG. 20 is a flow chart illustrating a method of processing a semiconductor wafer having a peripheral portion. The method, as shown at 130 includes providing an external support structure 50, 60. The method also includes, as shown at 132, restraining radially inward displacement of the wafer peripheral portion 20 with the external support structure 50, 60.

FIG. 21 is a flow chart illustrating a method of processing a semiconductor wafer 10 having a back side 14 and an opposite front side 12. The method includes, as shown at 140, providing a wafer support sheet 50 having a centrally positioned opening 52 therein. The method further includes, as shown at 142 attaching the wafer support sheet 50 to a peripheral portion 20 of the back side of the wafer 10 with a central portion of the wafer back side 14 exposed through the support sheet opening 52.

Although specific geometric shapes have been described herein for the wafer 10 support sheet 50 and support frame 60, it will be appreciated by those having skill in the art that other geometric shapes may be used. For example, if a wafer is formed in the shape of a square, rather than a circle, then corresponding square shapes might be used for the opening 52, 62 in the support sheet 50 and support frame 60. Also, although specific examples have been given for materials that have may be used to make the support sheet 50 and support frame 60, it will be appreciated that any number of materials might be used for this purpose so long as the materials have sufficient strength, rigidity, and appropriate dimensions for their intended purpose.

While certain illustrative embodiments of a semiconductor wafer and support structure therefor and associated methodology have been described in detail herein, it will be obvious to those with ordinary skill in the art after reading this disclosure that the disclosed semiconductor wafer and support structure and methodology may be variously otherwise embodied and employed. The appended claims are intended to be construed to include such variations except insofar as limited by the prior art.

1. A method of processing a semiconductor wafer having a peripheral portion comprising:
providing external support structure; and
restraining radially inward displacement of the peripheral portion with the external support structure.

2. The method of claim 1 wherein said restraining radially inward displacement of the peripheral portion comprises attaching the support structure to the peripheral portion of the wafer.

3. The method of claim 2 wherein attaching the external support structure to the peripheral portion comprises attaching a relatively flexible support sheet to the peripheral portion of the wafer.

4. The method of claim 3 wherein attaching the support structure to the peripheral portion of the wafer further comprises attaching the relatively flexible support sheet to a relatively rigid support frame.

5. The method of claim 4 wherein said attaching a relatively flexible support sheet to the peripheral portion comprises positioning a central opening in the support sheet so that it exposes a central portion of the wafer and attaching a portion of the support sheet positioned radially outwardly of the opening to the support frame.

6. The method of claim 5 wherein said attaching a portion of the support sheet to the support frame comprises attaching the portion of the support sheet positioned radially outwardly of the opening in the support sheet to a portion of the support frame positioned radially outwardly of a central opening in the support frame.

7. The method of claim 6:
wherein the wafer has a front side and an opposite back side, the support sheet has a front side and an opposite back side, the support frame has a front side and an opposite back side and each of the front sides of the wafer, support sheet and support frame face in a first direction;
wherein said attaching a relatively flexible support sheet to the peripheral portion of the wafer comprises attaching the second side of the support sheet to a peripheral portion of the first side of the wafer; and
wherein attaching the relatively flexible support sheet to a relatively rigid support frame comprises attaching the second side of the support sheet to the first side of the support frame.

8. A method of processing a semiconductor wafer having a back side and an opposite front side comprising:
providing a wafer support sheet having a centrally positioned opening therein; and
attaching the wafer support sheet to a peripheral portion of the back side of the wafer with a central portion of the wafer back side exposed through the support sheet opening.

9. The method of claim 8 comprising attaching the support sheet to a support frame.

10. The method of claim 9 comprising transporting the wafer, support sheet and support frame with an external transport mechanism that engages the support frame.

11. The method of claim 10, comprising applying a back side metal layer to the exposed portion of the wafer back side.

12. The method of claim 11 comprising removing the support sheet from the wafer.

13. The method of claim 12 comprising applying dicing tape to the back side of the wafer and the metal coating thereon and to the support frame and then dicing the wafer.

14. The method of claim 11 comprising applying dicing tape to the back side metal layer and the support sheet and then dicing the wafer.

15. The method of claim 8 comprising, prior to said attaching the wafer support sheet to a peripheral portion of the back side of the wafer:
applying a front side metal layer to the wafer front side;
applying back grind tape to the front side metal layer; and
back grinding the wafer to a predetermined thickness.

16. An assembly for producing a semiconductor chip having a front side metal layer and a back side metal layer comprising:
a semiconductor wafer having a front side and an opposite back side, said back side having a peripheral portion and a central portion, wherein a first metal layer is attached to said silicon wafer front side; and
a support sheet with an opening therein attached to said peripheral portion of said back side of said silicon wafer with said central portion of said wafer back side exposed through said support sheet opening.

17. The assembly of claim 16, further comprising a relatively rigid support frame having a central opening therein and wherein said support sheet is relatively flexible and is attached to said support frame.

18. The assembly of claim 17 comprising a second metal layer attached to said central portion of said back side of said silicon wafer.

19. The assembly of claim 17 wherein said central opening in said support frame is smaller than an outer periphery of said support sheet.

20. The assembly of claim 19 wherein said silicon wafer, said central opening in said support sheet and said central opening in said support frame are all substantially coaxial.
